(19) United States
(12) Patent Application Publication
(10) Pub. No.: US 2007/0052012 A1
(43) Pub. Date: Mar. 8, 2007

(54) Vertical tunneling nano-wire transistor

(75) Inventor: Leonard Forbes, Corvallis, OR (US)

Correspondence Address: LEFFERT JAY & POLGLAZE, P.A., P.O. BOX 581009, MINNEAPOLIS, MN, 55458-1009, US

(73) Assignee: Micron Technology, Inc.

(21) Appl. No.: 11/210,374

(22) Filed: Aug. 24, 2005

(51) Int. Cl. H01L 29/76; H01L 21/336

(52) U.S. Cl. 257/328; 438/268; 257/E27.096

(57) ABSTRACT

A vertical nano-wire transistor is formed on a substrate out of a vertical pillar having active regions of opposing conductivity in opposite ends of the pillar. In one embodiment, the source region is a p+ region in the substrate under the pillar and the drain region is an n+ region at the top of the pillar. A surround gate is formed around the pillar. The transistor operates by electron tunneling from the source valence band to the gate biasing induced n-type channels along the sidewalls of the pillar to the drain region, thus resulting in a drain current.

### TECHNICAL FIELD OF THE INVENTION

The present invention relates generally to electronic components and in particular the present invention relates to CMOS transistors.

### BACKGROUND OF THE INVENTION

Transistor lengths have become so small that current continues to flow when they are turned off, draining batteries and affecting performance. When the gate-source voltage, V_{gs}, of a metal oxide semiconductor (MOS) transistor is less than its voltage threshold, Vₜ, it is in the sub-threshold region. This is characterized by a exponential change in drain current with V_{gs}. Sub-threshold leakage currents are difficult to control and reduce in conventional nano-scale planar complementary metal oxide semiconductor (CMOS) transistor technology. As technology scales, sub-threshold leakage currents can grow exponentially and become an increasingly large component of total power dissipation. This is of great concern to designers of handheld or portable devices where battery life is important, so minimizing power dissipation while achieving satisfactory performance is an increasingly important goal.

Two-dimensional short channel effects in a typical prior art planar transistor structure, shown in FIG. 1, result in a sub-threshold slope on the order of 120 mV/decade to 80 mV/decade. An ideal slope would be approximately 60 mV/decade, as shown in FIG. 2. The low power supply voltages used in nano-scale CMOS circuits that are now on the order of 2.5 V exacerbate the problem.

The planar transistor of FIG. 1 is comprised of a substrate 100 in which two source/drain regions 101, 102 are implanted. A control gate 103 is formed over the channel region 105 in which a channel forms during operation of the transistor.

Future supply voltages are projected to become even lower, in the range of 1.2 V, as designers try to improve battery life and performance of electronic devices. At such power levels, there will not be enough voltage range to turn on a transistor. A significant voltage overdrive above the threshold voltage is typically required to turn-on a prior art transistor and turn-off the transistor sub-threshold leakage. This can be several multiples of the 100 mV/decade threshold voltage slope illustrated in FIG. 2. For good Iₒₙ/I_{off} ratios, the sub-threshold leakage current needs to be at least eight orders of magnitude or eight decades below the transistor current levels when the transistor is turned on. With a 1.2 V voltage range, there will not be enough voltage swing to allow both objectives: high on current and low sub-threshold leakage to be accomplished with conventional planar devices.

Gate body connected transistors as previously described in CMOS circuits provide a dynamic or changing threshold voltage, low when the transistor is on and a high threshold when it is off. Another alternative is using dual gated transistors. Yet another alternative is surrounding gate structures where the gate completely surrounds the transistor channel. This allows best control over the transistor channel but the structure has been difficult to realize in practice. Another technique has been to re-crystallize amorphous silicon that passes through a horizontal or vertical hole. None of these techniques, however, can have a sub-threshold slope less than the ideal characteristic of 60 mV/decade for a convention MOSFET.

For the reasons stated above, and for other reasons stated below that will become apparent to those skilled in the art upon reading and understanding the present specification, there is a need in the art for a device structure that has reduced sub-threshold leakage.

### SUMMARY

The above-mentioned problems with transistors and other problems are addressed by the present invention and will be understood by reading and studying the following specification.

The present invention encompasses a vertical tunneling, nano-wire transistor fabricated in sub-lithographic dimensions. The transistor comprises a substrate having a pillar. Source and drain regions are formed at opposite ends of the pillar. In one embodiment, the source region is p+ and the drain region is n+. A surround gate is formed around the pillar.

During operation, a bias on the surround gate and the drain region induces n-channels to form along the sidewalls of the pillar. Tunneling of electrons occurs from the source valence band to the induced channel regions resulting in drain current.

Further embodiments of the invention include methods and apparatus of varying scope.

### BRIEF DESCRIPTION OF THE DRAWINGS

FIG. 1 shows a cross-sectional view of a typical prior art planar CMOS transistor structure.

FIG. 2 shows a graphical plot of sub-threshold leakage current for a typical prior art CMOS transistor as compared to an ideal sub-threshold leakage characteristic.

FIG. 3 shows a schematic cross-sectional view of a vertical, nano-wire, silicon body transistor of the present invention.

FIGS. 4A and 4B show energy band diagrams of the electrical operation of the transistor embodiment of FIG. 3.

FIG. 5 shows a plot of the sub-threshold leakage current of the transistor embodiment of FIG. 3.

FIGS. 6A and 6B show top and side views, respectively, of one embodiment of a technique for etching silicon pillars in accordance with the vertical nano-wire transistor of the present invention.

FIGS. 7A and 7B show top and side views, respectively, of an alternate embodiment for etching silicon pillars in accordance with the vertical nano-wire transistor of the present invention.

FIG. 8 shows a top view of another step in accordance with the embodiment of FIGS. 7A and 7B for etching silicon pillars.

FIG. 9 shows an alternate embodiment of the nano-wire transistor of the present invention in accordance with the etching embodiment of FIGS. 8 and 9.

FIG. 10 shows yet another alternate embodiment of the nano-wire transistor of the present invention.

FIG. 11 shows a schematic diagram of one application of the tunneling nano-wire transistor of the present invention in a CMOS logic circuit.

FIG. 12 shows a schematic diagram of another application of the tunneling nano-wire transistor of the present invention in a CMOS logic circuit.

FIG. 13 shows a block diagram of one embodiment of a memory device incorporating the tunneling nano-wire transistor of the present invention.

FIG. 14 shows a block diagram of one embodiment of a memory module incorporating the tunneling nano-wire transistor embodiments of the present invention.

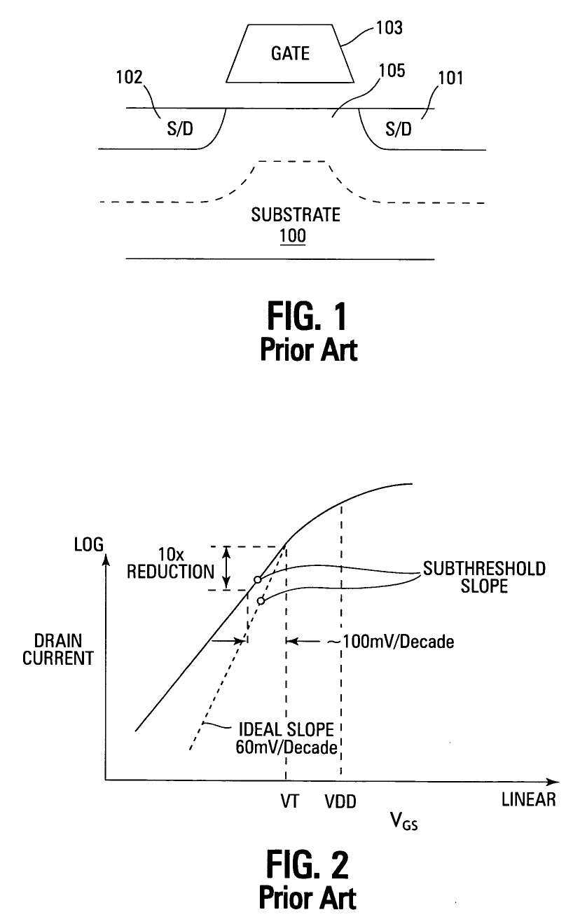

### DETAILED DESCRIPTION

In the following detailed description of the invention, reference is made to the accompanying drawings that form a part hereof and in which is shown, by way of illustration, specific embodiments in which the invention may be practiced. In the drawings, like numerals describe substantially similar components throughout the several views. These embodiments are described in sufficient detail to enable those skilled in the art to practice the invention. Other embodiments may be utilized and structural, logical, and electrical changes may be made without departing from the scope of the present invention. The following detailed description is, therefore, not to be taken in a limiting sense, and the scope of the present invention is defined only by the appended claims and equivalents thereof. The terms wafer or substrate used in the following description include any base semiconductor structure. Both are to be understood as including silicon-on-sapphire (SOS) technology, silicon-on-insulator (SOI) technology, thin film transistor (TFT) technology, doped and undoped semiconductors, epitaxial layers of a silicon supported by a base semiconductor structure, as well as other semiconductor structures well known to one skilled in the art. Furthermore, when reference is made to a wafer or substrate in the following description, previous process steps may have been utilized to form regions/junctions in the base semiconductor structure, and terms wafer or substrate include the underlying layers containing such regions/junctions.

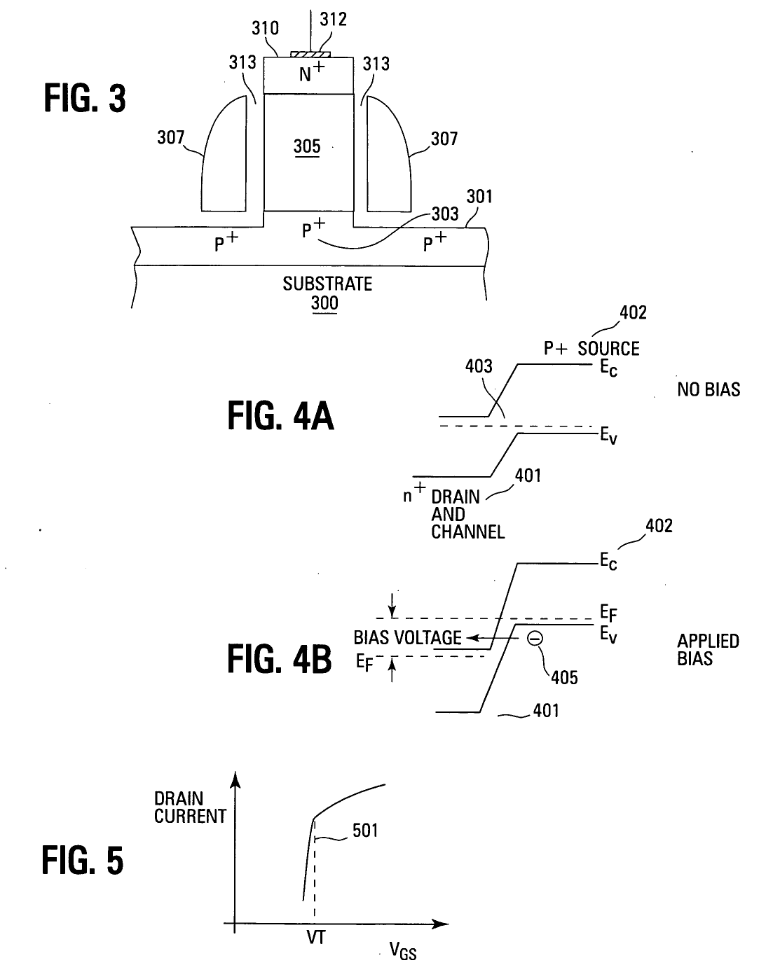

FIG. 3 illustrates cross-sectional view of one embodiment for a vertical tunneling, nano-wire transistor of the present invention. The illustrated embodiment is formed in a silicon substrate 300 or n+ well. Alternate embodiments may use other conductivity doping for the substrate.

Instead of the conventional n+ source region formed in the substrate 300, the source 303 of the present invention is p+ doped. Additionally, the source wiring 301 that couples the source to other components in a circuit is also p+ doped.

A lightly doped, thin p-type nano-wire body 305 is formed over the source region 303. In one embodiment, this is implemented in 0.1 micron technology such that the transistor has a height of approximately 100 nm and a thickness in the range of 25 to 50 nm. Alternate embodiments may use other dimensions. Alternate embodiments may use other heights and/or thickness ranges.

An n+ doped drain region 310 is formed at the top of the silicon body 305. A contact 312 is formed on the drain region 310 to allow connection of the transistor's drain region to other components of an electronic circuit. This connection may be a metal or some other material.

A gate insulator layer 313 is formed around the thin nano-wire body 305. The insulator can be an oxide or some other type of dielectric material.

A control gate 307 is formed around the insulator layer 313. As is well known in the art, proper biasing of the control gate 307 causes an n-channel to form in a channel region between the source 303 and drain 310 regions. A more detailed discussion of the operation of the transistor of the present invention is discussed subsequently.

FIGS. 4A and 4B illustrate energy band diagrams of the operation of the transistor of FIG. 3. The upper line of each figure indicating the energy of the conduction band and the lower line indicating the energy of the valence band. FIG. 4A illustrates a no bias condition for the transistor. The diagram shows the channel and n+ drain 401 and p+ source 402. In the non-conducting condition, a large barrier 403 exists between the drain 401 and source 402 regions.

FIG. 4B illustrates that applying a bias to the gate creates a conducting condition in which an electron channel is induced to form once the electron concentration is degenerated. A tunnel junction 405 is formed at the source side 402 of the channel.

Applying a drain bias causes band bending and the n-type region conduction band to be below the valence band edge in the source region. Electrons can then tunnel from the source valence band to the induced n-type channel region resulting in drain current. Since there can be no tunneling until the conduction band edge in the channel is drawn below the valence band in the source, the turn-on characteristic is very sharp and the sub-threshold slope approaches the ideal value for a tunneling transistor of zero mV/decade as illustrated in FIG. 5.

FIG. 5 illustrates a plot of drain current versus the gate-to-source voltage (V_{GS}) of the transistor. This plot shows the very steep sub-threshold slope “S” 501 that results from the biasing of the embodiments of the nano-wire transistor of the present invention. The vertical, drain current axis of FIG. 5 is a log scale while the horizontal, V_{GS} axis is linear.

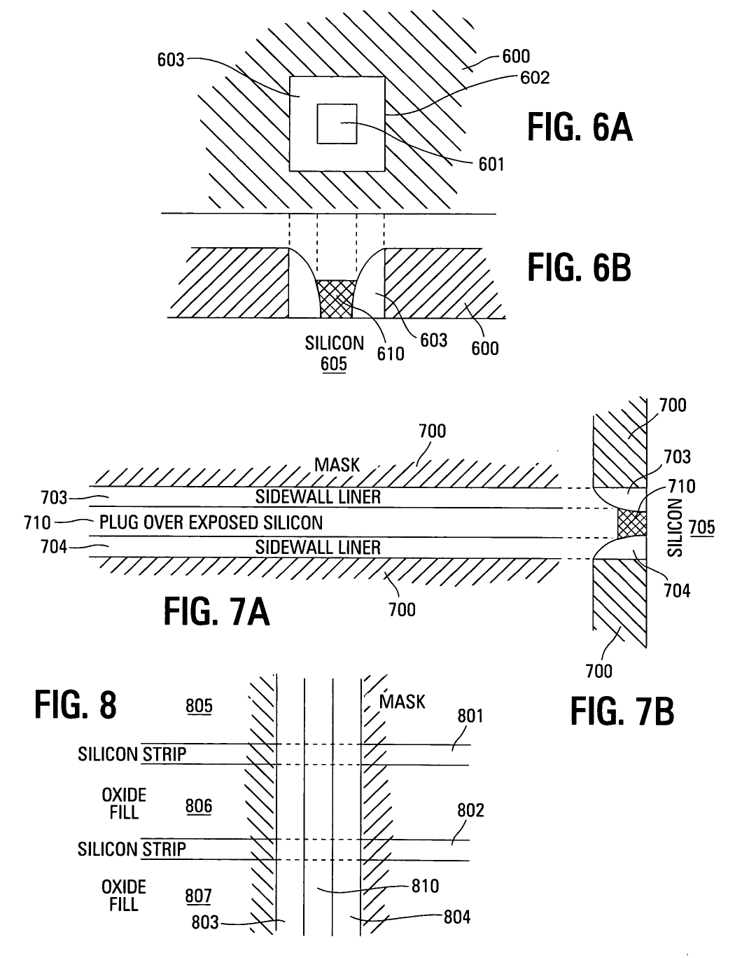

FIGS. 6A and 6B illustrate one embodiment for a method for fabricating the vertical nano-wire transistors of the present invention. In this embodiment, a surface of a silicon wafer 605 is very heavily doped n+ by ion implantation and an oxide layer 600 is deposited. Holes 601 are formed in the oxide layer and the dimensions of the holes then reduced 602 by a sidewall 603 spacer technique. These reduced dimension holes 602 are smaller than lithographic dimensions.

The holes 602 are filled with a masking layer 610 and the oxide 600 and sidewall spacers 603 are removed leaving only the small masking dot 610. Silicon pillars are then etched.

FIGS. 7A and 7B illustrate an alternate embodiment for fabrication of the vertical nano-wire transistors of the present invention. This embodiment etches strips in an oxide mask 700 that has been formed over the silicon 705. The dimensions of the strips are then reduced by deposition of sidewall spacers 703, 704.

An etch mask 710 is then deposited as a plug over the exposed silicon 705. The thickness of the etch mask 710 is thinned leaving only a strip of sub-lithographic dimensions. The oxide mask 700 and sidewall spacers 703, 704 are removed and rows of silicon 705 etched such that the etch mask 710 produces silicon strips.

FIG. 8 illustrates a top view of the continuing steps of the fabrication process of FIGS. 7A and 7B. This figure shows the resulting silicon strips 801, 802 from the steps of FIGS. 7A and 7B. The resulting structure is back filled with oxide 805-807 and planarized.

The process is then repeated in the orthogonal direction. The oxide is etched and sidewalls 803, 804 are deposited. The etch mask plug 810 is formed between the sidewalls 803, 804. The resulting etch process leaves only the sub-lithographic, nano-wire pillars of silicon.

After either of the fabrication processes illustrated in FIGS. 6-8, the p+ source regions can then be implanted. Since the p+ doping for the source and wiring is lower than the n+ doping for the drain regions in the tops of the pillars, the tops do not require a mask since they will remain n+.

It can be seen from the above embodiments that, unlike prior n-channel transistor structures and fabrication processes, the source of the vertical, nano-wire transistor of the present invention are doped p+ instead of n+ or implanted n+.

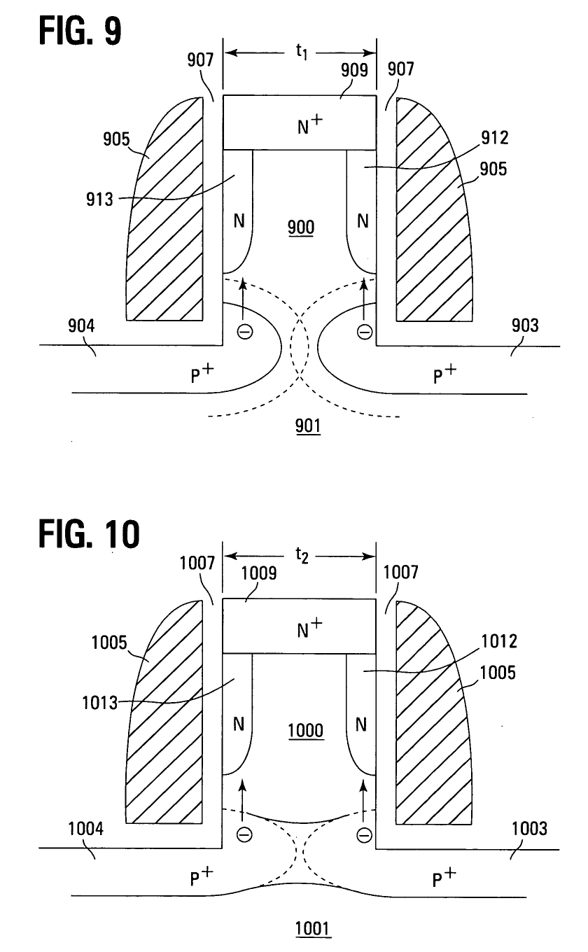

FIG. 9 illustrates one embodiment structure of the vertical, nano-wire transistor of the present invention. This embodiment differs from previously described n-channel, vertical transistors in that that source is formed from p+ regions that are formed under the sidewalls of the transistor. If the pillars are thin enough and/or the p+ regions diffuse, the p+ regions will merge under the pillar.

The embodiment of FIG. 9 is comprised of a substrate 901 that, in one embodiment, is silicon. A lightly doped, p-type pillar 900 is formed in the silicon substrate 901 and has a thickness of t₁. In one embodiment, t₁ is in the range of 25-50 nm. Alternate embodiments may use other thickness ranges. The pillar has an n+ region 909 formed at the top. A gate insulator 907 is grown or deposited around the pillar. Over the gate insulator 907, the surround gate 905 is formed. In one embodiment, the surround gate is formed by a sidewall etch technique.

The p+ source regions 903, 904 are formed under the sidewalls of the transistor. As explained previously, these regions merge during operation to form one source region. Under a bias condition, the electrons tunnel vertically from the combined p+ regions 903, 904 to vertical n-channels 912, 913 formed along the sides of the transistor pillar 900.

FIG. 10 illustrates another alternate embodiment of the vertical, nano-wire transistor of the present invention. This embodiment is substantially similar to the embodiment of FIG. 9 but with a thinner pillar dimension.

The embodiment of FIG. 10 is comprised of a substrate 1001 in which the lightly doped p-type pillars 1000 of the transistors are formed. The pillars 1000 each contain the n+ drain region 1009 at the top. A gate insulator 1007, such as oxide or some other dielectric, is formed around the pillar. The surround gate 1005, such as polysilicon, is formed around the gate insulator 1007.

The p+ source regions 1003, 1004 are formed in the substrate under the sidewalls of the pillar 1000. As in previous embodiments, under a bias condition, the electrons tunnel vertically to n-channels 1012, 1013 created along the sidewalls between the merged source region 1003, 1004 and the drain region 1009.

In this embodiment, the pillar is formed to a thickness of t₂ that is also in the range of 25-50 nm. Alternate embodiments may use other thickness ranges. In this embodiment, t₂ is less than t₁ of the embodiment of FIG. 9.

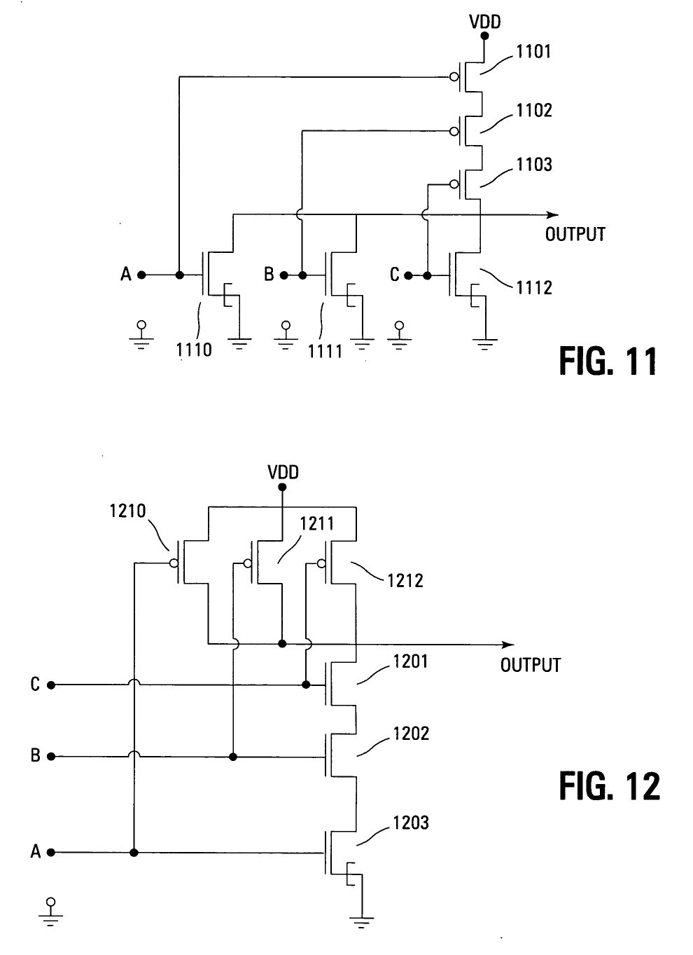

FIG. 11 illustrates one embodiment of an application of the vertical tunneling, nano-wire transistor of the present invention. This application incorporates the transistor into a NOR gate CMOS logic circuit. As is well known to one skilled in the art, this circuit operates by the logic levels introduced at the A, B, and C inputs. A logic low input signal on any of these inputs turns on its respective PMOS transistor 1101-1103 and turns off its respective vertical tunneling, nano-wire transistor 1110-1112. A logic high input signal has the opposite effect. Turning on any of the vertical tunneling, nano-wire transistors 1110-1112 has the effect of bringing the output to ground (i.e., a logic 0). Turning on all of the PMOS transistors 1101-1103 has the effect of taking the output to V_{DD} (i.e., a logic 1).

FIG. 12 illustrates another embodiment of an application of the vertical tunneling, nano-wire transistor of the present invention. This application incorporates the transistor into a NAND gate CMOS logic circuit by replacing the NMOS transistor closest to V_{SS} with the tunneling, nano-wire transistor 1203. As is well known in the art, the NAND circuit operates by a logic low input signal on any of the three inputs A, B, C causes its respective PMOS device 1210-1212 to turn on and pull the output to a logic high. A logic high on all of the inputs turns on the respective NMOS transistors 1201-1202 and vertical tunneling, nano-wire transistor 1203 that pulls the output to a logic low.

The nano-wire transistors of the present invention, in both of these circuits, provides substantially reduced sub-threshold leakage current and, thus, reduced power operation of CMOS circuits. These embodiments are for purposes of illustration only since the vertical tunneling, nano-wire transistor of the present invention can be used in any transistor circuit.

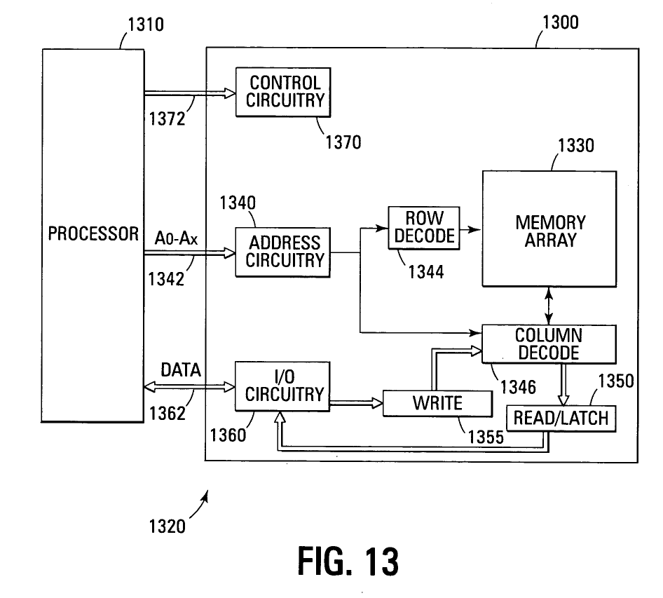

FIG. 13 illustrates a functional block diagram of a memory device 1300 of one embodiment of the present invention. The memory device 1300 is another embodiment of a circuit that can include the nano-wire transistors of the present invention.

The memory device includes an array of memory cells 1330 such as non-volatile memory cells or DRAM type memory cells. The memory array 1330 is arranged in banks of rows and columns along word lines and bit lines, respectively.

An address buffer circuit 1340 is provided to latch address signals provided on address input connections A0-Ax 1342. Address signals are received and decoded by a row decoder 1344 and a column decoder 1346 to access the memory array 1330. It will be appreciated by those skilled in the art, with the benefit of the present description, that the number of address input connections depends on the density and architecture of the memory array 1330. That is, the number of addresses increases with both increased memory cell counts and increased bank and block counts.

The memory device 1300 reads data in the memory array 1330 by sensing voltage or current changes in the memory array columns using sense/latch circuitry 1350. The sense/latch circuitry, in one embodiment, is coupled to read and latch a row of data from the memory array 1330. Data input and output buffer circuitry 1360 is included for bi-directional data communication over a plurality of data connections 1362 with the controller 1310). Write circuitry 1355 is provided to write data to the memory array.

Control circuitry 1370 decodes signals provided on control connections 1372 from the processor 1310. These signals are used to control the operations on the memory array 1330, including data read, data write, and erase operations. The control circuitry 1370 may be a state machine, a sequencer, or some other type of controller.

The memory device illustrated in FIG. 13 has been simplified to facilitate a basic understanding of the features of the memory. A more detailed understanding of internal circuitry and functions of flash memories and/or DRAM's are known to those skilled in the art.

The vertical tunneling, nano-wire transistors of the present invention can be used in the memory device of FIG. 13, as well as the subsequently discussed memory module, as select transistors, control transistors, and in logic elements such as NAND and NOR gates as discussed previously.

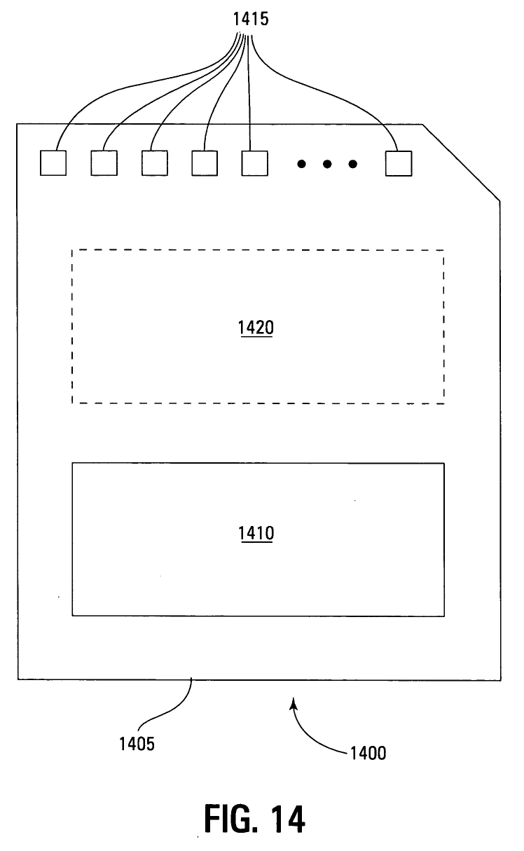

FIG. 14 is an illustration of an exemplary memory module 1400. Memory module 1400 is illustrated as a memory card, although the concepts discussed with reference to memory module 1400 are applicable to other types of removable or portable memory, e.g., USB flash drives, and are intended to be within the scope of “memory module” as used herein. In addition, although one example form factor is depicted in FIG. 14, these concepts are applicable to other form factors as well.

In some embodiments, memory module 1400 will include a housing 1405 (as depicted) to enclose one or more memory devices 1410, though such a housing is not essential to all devices or device applications. At least one memory device 1410 is a non-volatile memory [including or adapted to perform elements of the invention]. Where present, the housing 1405 includes one or more contacts 1415 for communication with a host device. Examples of host devices include digital cameras, digital recording and playback devices, PDAs, personal computers, memory card readers, interface hubs and the like. For some embodiments, the contacts 1415 are in the form of a standardized interface. For example, with a USB flash drive, the contacts 1415 might be in the form of a USB Type-A male connector. For some embodiments, the contacts 1415 are in the form of a semi-proprietary interface, such as might be found on CompactFlash™ memory cards licensed by SanDisk Corporation, Memory Stick™ memory cards licensed by Sony Corporation, SD Secure Digital™ memory cards licensed by Toshiba Corporation and the like. In general, however, contacts 1415 provide an interface for passing control, address and/or data signals between the memory module 1400 and a host having compatible receptors for the contacts 1415.

The memory module 1400 may optionally include additional circuitry 1420 which may be one or more integrated circuits and/or discrete components. For some embodiments, the additional circuitry 1420 may include a memory controller for controlling access across multiple memory devices 1410 and/or for providing a translation layer between an external host and a memory device 1410. For example, there may not be a one-to-one correspondence between the number of contacts 1415 and a number of I/O connections to the one or more memory devices 1410. Thus, a memory controller could selectively couple an I/O connection (not shown in FIG. 14) of a memory device 1410 to receive the appropriate signal at the appropriate I/O connection at the appropriate time or to provide the appropriate signal at the appropriate contact 1415 at the appropriate time. Similarly, the communication protocol between a host and the memory module 1400 may be different than what is required for access of a memory device 1410. A memory controller could then translate the command sequences received from a host into the appropriate command sequences to achieve the desired access to the memory device 1410. Such translation may further include changes in signal voltage levels in addition to command sequences.

The additional circuitry 1420 may further include functionality unrelated to control of a memory device 1410 such as logic functions as might be performed by an ASIC (application specific integrated circuit). Also, the additional circuitry 1420 may include circuitry to restrict read or write access to the memory module 1400, such as password protection, biometrics or the like. The additional circuitry 1420 may include circuitry to indicate a status of the memory module 1400. For example, the additional circuitry 1420 may include functionality to determine whether power is being supplied to the memory module 1400 and whether the memory module 1400 is currently being accessed, and to display an indication of its status, such as a solid light while powered and a flashing light while being accessed. The additional circuitry 1420 may further include passive devices, such as decoupling capacitors to help regulate power requirements within the memory module 1400.

### CONCLUSION

In summary, a very thin, vertical nano-wire transistor NMOS FET has a p+ source, rather than an n+ source as in prior art transistors. In this configuration, electrons tunnel from the p+ source to induced n-channels along the pillar sidewalls. Such a configuration provides an ideal sub-threshold slope that is substantially close to 0 mV/decade and thus obtain low sub-threshold leakage current in CMOS circuits. The substantially reduced leakage current reduces the power requirements for electronic circuits.

Although specific embodiments have been illustrated and described herein, it will be appreciated by those of ordinary skill in the art that any arrangement that is calculated to achieve the same purpose may be substituted for the specific embodiments shown. Many adaptations of the invention will be apparent to those of ordinary skill in the art. Accordingly, this application is intended to cover any adaptations or variations of the invention. It is manifestly intended that this invention be limited only by the following claims and equivalents thereof.

What is claimed is:

1. A vertical, tunneling nano-wire transistor comprising:
a substrate having a pillar;
source and drain regions at opposite ends of the pillar wherein the source region has opposite conductivity from the drain region; and
a surround gate formed around the pillar.

2. The transistor of claim 1 wherein the transistor is implemented in 0.1 micron technology.

3. The transistor of claim 1 wherein the pillar has a height of 100 nm.

4. The transistor of claim 1 wherein the pillar has a thickness substantially in a range of 25 to 50 nm.

5. The transistor of claim 1 wherein the source region is a p+ region and the drain region is an n+ region.

6. The transistor of claim 1 wherein the drain region is at the top of the pillar and the source region is at the bottom of the pillar.

7. A vertical tunneling, nano-wire transistor comprising:
a substrate having a lightly doped, p-type pillar;
an n+ drain region formed at the top of the pillar;
a p+ source region formed at the bottom of the pillar; and
a surround gate formed around the pillar.

8. The transistor of claim 7 and further including p+ wires doped into the substrate and coupled to the source region.

9. The transistor of claim 7 wherein n-channels are created along opposing sides of the pillar between the source and drain regions in response to a bias on the surround gate.

10. The transistor of claim 9 wherein the bias on the surround gate and a bias on the drain region causes electron tunneling from the p+ source valence band.

11. The transistor of claim 7 and further including a gate dielectric formed between the pillar and the surround gate.

12. A vertical tunneling, nano-wire transistor comprising:
a substrate having a lightly doped, p-type pillar;
an n+ drain region formed at the top of the pillar;
a pair of p+ source regions formed in the substrate, each region formed under opposing sidewalls of the pillar such that the source regions are adapted to merge during operation of the transistor;
a gate dielectric formed around the pillar; and
a surround gate formed around the gate dielectric.

13. The transistor of claim 12 wherein the gate dielectric is comprised of an oxide and the surround gate is a polysilicon.

14. The transistor of claim 12 wherein the substrate is silicon.

15. The transistor of claim 12 wherein the pair of p+ source regions are diffuse.

16. A method of operation of a vertical, nano-wire transistor having a source region and a drain region at opposing ends of a substrate pillar, the source and drain regions having opposite conductivity, a surrounding gate formed around the pillar, the method comprising:
biasing the surrounding gate to create an n-type channel between the source and drain regions along opposing sides of the pillar; and
biasing the drain region to enable electrons tunneling from a valence band of the source region to the induced n-type channels.

17. The method of claim 16 wherein the tunneling occurs after a conduction band edge of the n-type channels is drawn below the valence band of the source region.

18. A method for fabricating vertical tunneling, nano-wire transistors on a substrate, the method comprising:
doping a layer of the surface of the substrate to an n+ conductivity;
forming an oxide layer over the substrate surface;
forming holes in the oxide layer;
reducing dimensions of the holes;
filling reduced hole with pillar masking layer;
removing the oxide layer;
etching pillars into the substrate in response to the pillar masking layer such that the n+ layer is a drain region at the top of each pillar;
doping p+ regions into the substrate below each pillar; and
forming surrounding gate around pillar.

19. The method of claim 18 wherein the doping is performed by ion implantation.

20. The method of claim 18 wherein the hole dimensions are reduced by sidewall spacers that are removed when the oxide layer is removed.

21. The method of claim 18 and further including forming a gate dielectric between the pillar and the surrounding gate.

22. The method of claim 18 wherein implanting the p+ regions includes creating p+ source regions such that vertical tunneling from the source regions can occur in response to biasing of the surrounding gate and drain region.

23. A method for fabricating vertical tunneling, nano-wire transistors on a substrate, the method comprising:
doping a layer of the surface of the substrate to an n+ conductivity;
forming an oxide layer over the substrate surface;
etching strips into the oxide layer;
reducing the width of the strips with sidewall spacers;
depositing an etch mask in the reduced width of each strip;
removing the oxide layer and sidewall spacers;
etching the substrate to produce a silicon strip structure;
filling the silicon strip structure with oxide;
forming sub-lithographic, nano-wire pillars from the silicon strip structure; and
implanting p+ regions in the substrate below the pillars.

24. A memory device comprising:
control circuitry that controls operation of the memory device;
a memory array comprising a plurality of memory cells; and
a plurality of vertical tunneling, nano-wire transistors, each transistor comprising:
a substrate having a pillar;
source and drain regions at opposite ends of the pillar wherein the source region has opposite conductivity from the drain region; and
a surround gate formed around the pillar.

25. The memory device of claim 24 wherein the memory cells are non-volatile memory cells.

26. The memory device of claim 24 wherein the memory cells are DRAM cells.

27. A memory system fabricated on a substrate, the system comprising:
control circuitry that controls operation of the memory system;
a memory array comprising a plurality of memory cells; and
a plurality of vertical tunneling, nano-wire transistors, each transistor comprising:
a substrate having a pillar;
source and drain regions at opposite ends of the pillar wherein the source region has opposite conductivity from the drain region; and
a surround gate formed around the pillar.

28. A memory module comprising:
a memory device comprising:
control circuitry that controls operation of the memory device;
a memory array comprising a plurality of memory cells; and
a plurality of vertical tunneling, nano-wire transistors, each transistor comprising:
a substrate having a pillar;
source and drain regions at opposite ends of the pillar wherein the source region has opposite conductivity from the drain region; and
a surround gate formed around the pillar; and
a plurality of contacts configured to provide selective contact between the memory device and a host system.

29. The module of claim 28 and further including a memory controller coupled to the memory device for controlling operation of the memory device in response to the host system.

30. The module of claim 28 wherein a subset of the plurality of nano-wire transistors are coupled to provide logic functions in the memory module.
